(19) United States
(12) Patent Application Publication
(10) Pub. No.: US 2026/0182329 A1
(43) Pub. Date: Jun. 25, 2026

(54) INTEGRATED CIRCUITS (ICS) INCLUDING POWER AMPLIFIER CIRCUITS AND BACK SIDE PASSIVE COMPONENTS AND METHODS OF MAKING

(71) Applicant: QUALCOMM Incorporated, San Diego, CA (US)

(72) Inventors: Jiaping Zhang, San Diego, CA (US); Chenliang Du, San Diego, CA (US); Yuanzheng Yue, San Diego, CA (US); Sameer Sunil Vadhavkar, San Diego, CA (US); Anirudh Bhat, San Diego, CA (US)

(21) Appl. No.: 18/999,294

(22) Filed: Dec. 23, 2024

(51) Int. Cl. H01L 23/48; H01L 21/768; H01L 25/18; H10D 1/20; H10D 62/832; H10D 62/85

(52) U.S. Cl. CPC H10W 20/20; H10D 1/20; H10W 20/023; H10W 90/00; H10D 62/8325; H10D 62/8503

(57) ABSTRACT

Passive components formed in the metal layers on the front side of a semiconductor die, where active circuit components are formed, can occupy a relatively large area of an integrated circuit (IC). Since cost of an IC is directly dependent on area, reducing area of passive components on the front side of the semiconductor die can reduce the cost of the IC. An exemplary integrated circuit including a power amplifier circuit on a first side and a passive electronic component on a second side can reduce overall size and cost. The passive electronic component is coupled to the power amplifier circuit by through-die vias extending through the semiconductor die between the first side and the second side. In some examples, the passive electronic component is an inductor coil formed in metal layers on the second side of the semiconductor die. In some examples, the semiconductor die is a gallium arsenide (GaAs) substrate.

### TECHNICAL FIELD

The technology of the disclosure relates generally to power amplifiers on semiconductor dies in electronic devices and, more particularly, to reducing the die area of the power amplifier to reduce cost of electronic devices.

### BACKGROUND

The capabilities of electronic devices, such as cell phones, tablets, laptops, etc., are made possible by integrated circuits (ICs). Consumer demand drives both the cost and the performance of electronic devices, but those demands conflict with each other. As circuits are added to increase functional capability, the size of semiconductor dies increases to accommodate the additional circuits. Additionally, as ICs include more circuits, they demand more power and larger electronic components in a power amplifier to provide such power, which increases the size of a die containing the power amplifier. An increase in the size of semiconductor dies increases their cost. Thus, there is a need for ways to provide the power needed in ICs as power demands increase while minimizing or decreasing the area of a power amplifier die.

### SUMMARY

Aspects disclosed in the detailed description include integrated circuits (ICs) including power amplifier circuits and back side passive components. Related methods of making ICs with power amplifier circuits and back side passive components are also disclosed. Passive components formed in the metal layers on the front side of a semiconductor die, where active circuit components are formed, can occupy a relatively large area of an IC. Since the cost of an IC is directly dependent on area, reducing the area of passive components on the front side of the semiconductor die can reduce the cost of the IC. An exemplary IC including a power amplifier circuit on a first side and a passive electronic component on a second side can reduce overall size and cost. The passive electronic component is coupled to the power amplifier circuit by through-die vias extending through the semiconductor die between the first side and the second side. In some examples, the passive electronic component is an inductor coil formed in metal layers on the second side of the semiconductor die. In some examples, the semiconductor die is a gallium arsenide (GaAs) substrate.

In this regard, in one aspect, an IC is disclosed. The IC includes a semiconductor die, a power amplifier circuit on a first side of the semiconductor die, a passive electric component in at least one metal layer on a second side of the semiconductor die, and through-die vias extending between the power amplifier circuit and the passive electric component through the semiconductor die.

In another aspect, a method of making an IC is disclosed. The method includes forming a semiconductor die, forming a power amplifier circuit on a first side of the semiconductor die, forming a passive electric component in at least one metal layer on a second side of the semiconductor die, and forming through-die vias extending between the power amplifier circuit and the passive electric component through the semiconductor die.

In another aspect, a device package including a laminated substrate including a plurality of circuits and an IC is disclosed. The IC includes a semiconductor die, a power amplifier circuit on a first side of the semiconductor die, at least one metal layer configured to form a passive electric component on a second side of the semiconductor die, and through-die vias extending from the power amplifier circuit through the semiconductor die to the passive electric component. The device package further includes conductive pillars extending between the laminated substrate and the first side of the semiconductor die to couple the plurality of circuits to the power amplifier circuit.

### BRIEF DESCRIPTION OF THE DRAWINGS

FIG. 1 is a plan view of a front side of a semiconductor die including an inductor coil in a power amplifier circuit;

FIG. 2 is a cross-sectional side view of a device package including a power amplifier on first side of a semiconductor die as shown in FIG. 1 facing a package substrate that may be employed in a device package in an electronic device;

FIG. 3 is a cross-sectional side view of a device package including a power amplifier circuit on a first side of a semiconductor die and an inductor coil on a second side of the semiconductor die and coupled to the power amplifier circuit by through-die vias;

FIG. 4 is a plan view of a first side of the semiconductor die in FIG. 3 showing the addition of via contact pads for coupling the through-die vias to the power amplifier circuit and also showing area that is unused with the inductor coil on the second side, making an area reduction of the die possible;

FIG. 5 is a flowchart of a method of making the semiconductor die in FIGS. 3 and 4 including a first side power amplifier circuit and a second side inductor coil on the semiconductor die;

FIG. 6 is flowchart of a more detailed method of making the semiconductor die in FIGS. 3 and 4;

FIGS. 7A-7C show a first example of a through-die via that may be included in the semiconductor die in FIGS. 3 and 4 at stages of manufacture;

FIGS. 8A and 8B show a second example of a through-die via that may be included in the semiconductor die in FIGS. 3 and 4 at stages of manufacture;

FIG. 9 is a block diagram of an exemplary wireless communication device that may include the device package in FIG. 3, in which an inductor coil for a power amplifier circuit is on a back side of an semiconductor die to reduce die area; and

FIG. 10 is a block diagram of an exemplary processor-based system that can be disposed in a device package including a power amplifier circuit on a front side of an IC die with an inductor coil on a back side to reduce die area.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include integrated circuits (ICs) including power amplifier circuits and back side passive components. Related methods of making ICs with power amplifier circuits and back side passive components are also disclosed. Passive components formed in the metal layers on the front side of a semiconductor die, where active circuit components are formed, can occupy a relatively large area of an IC. Since the cost of an IC is directly dependent on area, reducing the area of passive components on the front side of the semiconductor die can reduce the cost of the IC. An exemplary IC including a power amplifier circuit on a first side and a passive electronic component on a second side can reduce overall size and cost. The passive electronic component is coupled to the power amplifier circuit by through-die vias extending through the semiconductor die between the first side and the second side. In some examples, the passive electronic component is an inductor coil formed in metal layers on the second side of the semiconductor die. In some examples, the semiconductor die is a gallium arsenide (GaAs) substrate.

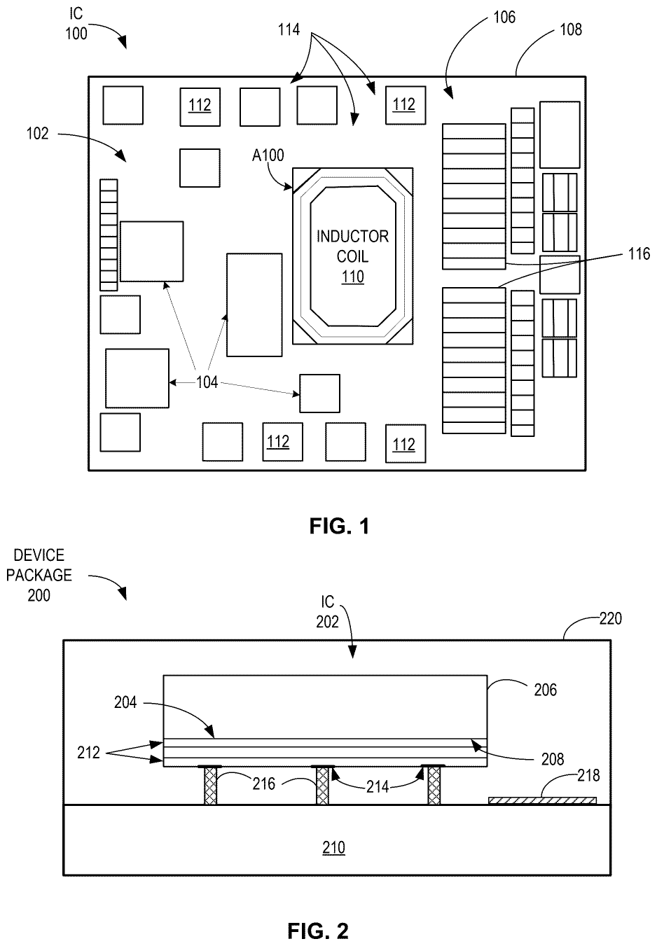

FIG. 1 is a plan view of an integrated circuit (IC) 100 including a power amplifier circuit 102 that includes various electronic components 104, both passive and active, on a front side 106 of a semiconductor die 108. The passive components of the power amplifier circuit 102 include, for example, an inductor coil 110 and contact pads 112 formed in metal layers 114. The contact pads 112 are provided for coupling the power amplifier circuit 102 to an external circuit (not shown). Active components include power transistors 116 formed in the semiconductor die 108. An area A100 of the semiconductor die 108 is determined by the number and size of the electronic components 104, the inductor coil 110, the power transistors 116, etc. and the sizes of such components increase with the power requirements of the power amplifier circuit 102. As shown in FIG. 1, the component of the power amplifier circuit 102 having the greatest impact on the area A100 is the inductor coil 110.

FIG. 2 is a cross-sectional side view of a device package 200 including an IC 202 including a power amplifier circuit 204 on a semiconductor die 206, as shown in FIG. 1. The IC 202 has a front side 208 facing a package substrate 210 that may be employed in an electronic device (not shown). The power amplifier circuit 204 is formed, at least in part, in metal layers 212 on the front side 208 of the semiconductor die 206. Contact pads 214 are formed in the metal layers 212 on the front side 208 to couple to conductive pillars 216. The conductive pillars 216 extend between the front side 208 of the IC 202 and the package substrate 210. The conductive pillars 216 are provided to conduct power from the power amplifier circuit 204 to other circuits 218 through the package substrate 210. The other circuits 218 may be formed directly on the package substrate 210 or may be in other ICs (not shown) coupled to the package substrate 210. The package substrate 210 may comprise a laminate including metal tracks in metal layers (not shown). The IC 202 is enveloped in a molding compound 220 that may provide protection from electrical shorts, water, chemicals, and physical damage. The device package 200 may be employed in cell phones or two-way radios, for example, which have a limited size but need high power for communication.

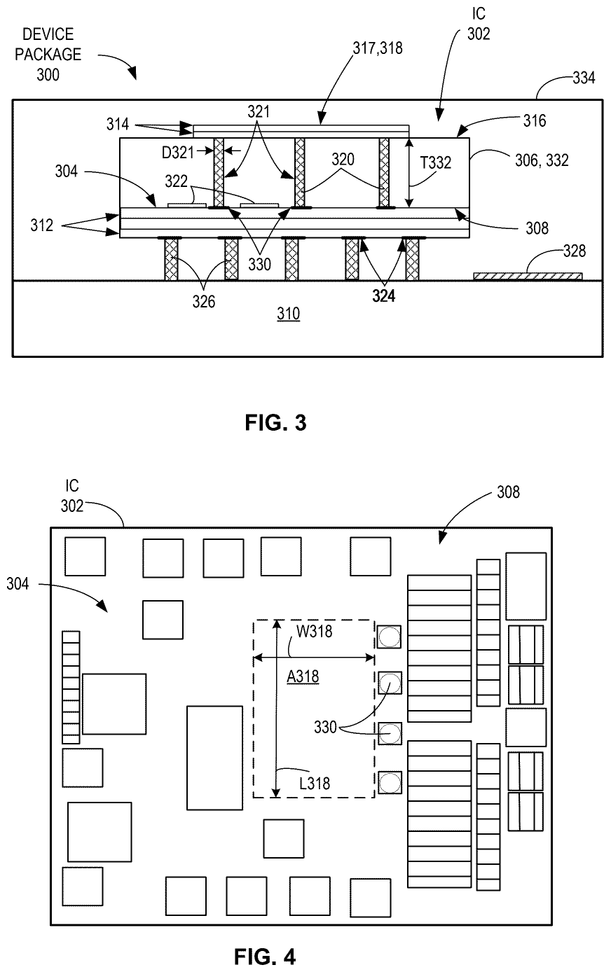

FIG. 3 is a cross-sectional side view of a device package 300 including an IC 302 including a power amplifier circuit 304 on a semiconductor die 306. The IC 302 has a first side (“front side”) 308 facing a package substrate 310, together forming the device package 300 that may be employed in an electronic device (not shown). The power amplifier circuit 304 is formed in first metal layers 312 on the front side 308 and couples to at least one second metal layer 314 on a second side (“back side”) 316 of the semiconductor die 306. For example, there may be multiple (e.g., up to three or more) second metal layers 314 in which passive electronic components may be formed. In this example, a passive electronic component 317 formed in the at least one second metal layer 314 may be an inductor coil 318. In some examples, the inductor coil 318 may comprise a multi-layer inductor coil formed in the second metal layers 314. In some examples, the passive electronic component 317 may comprise a capacitor, such as a metal-insulator-metal (MIM) capacitor. In this context, the term “inductor coil” refers to an inductor or a portion of an inductor formed of metal traces in one or more of the second metal layers 314, where the metal traces extend on (e.g., parallel to) the second side 316 of the semiconductor die 306 in a loop, circle, ellipse, square, rectangle or any other two-dimensional shape that provides inductance. The inductor coil 318 may include one or more of such shapes in up to three, or more, of the second metal layers 314 to increase the total inductance.

The power amplifier circuit 304 formed on the front side 308 of the semiconductor die 306 is coupled to the inductor coil 318 by through-die vias 320. The through-die vias 320 may be copper or another conductive metal extending between the power amplifier circuit 304 on the front side 308 and the passive electronic components, such as the inductor coil 318 on the back side 316 through the semiconductor die 306. Forming the through-die vias 320 may include etching holes 321 through the semiconductor die 306 and filling the holes 321 with a conductive metal, such as copper. A diameter D321 of the holes 321 and the through-die vias 320 may be in a range of twenty microns (20 μm) to two hundred microns (200 μm). In some examples, the diameter D321 of the through-die vias 320 may be in a range of sixty microns (60 μm) to eighty microns (80 μm).

The power amplifier circuit 304 may include power transistors 322 formed in the front side 308 of the semiconductor die 306. In this regard, the semiconductor die 306 may comprise a gallium arsenide (GaAs) substrate 332 and the power transistors 322 may be formed of GaAs. The semiconductor die 306 may, in a non-limiting example, have a thickness T332, in a direction orthogonal to the back side 316, in a range of fifty microns (50 μm) to two hundred microns (200 μm) between the front side 308 and the back side 316. In some examples, the thickness T332 may be in a range of one hundred forty microns (140 μm) to one hundred and sixty microns (160 μm). The semiconductor die 306 may alternatively comprise any of silicon carbide (SiC), gallium nitride (GaN), silicon (Si), and sapphire.

The front side 308 of the semiconductor die 306 may include various electronic components (not shown), such as those included in the power amplifier circuit 204. The power amplifier circuit 304 includes contact pads 324 for first conductive pillars 326 on the front side 308 of the semiconductor die 306. The contact pads 324 couple the power amplifier circuit 304 to the package substrate 310 to provide power from the power amplifier circuit 304 to other circuits 328 through the device package 300. The power amplifier circuit 304 also includes via pads 330 on the front side 308 of the semiconductor die 306 to couple the power amplifier circuit 304 to the through-die vias 320 that extend through the semiconductor die 306.

The IC 302 may be enveloped in a protective compound 334. With the inductor coil 318 located on the back side 316, the front side 308 of the semiconductor die 306 does not need to include the inductor coil 318. Accordingly, assuming the power amplifier circuit 204 in FIG. 2 and the power amplifier circuit 304 have the same components and are each packaged as densely as possible, the semiconductor die 306 may be smaller than the semiconductor die 206 in FIG. 2, as is more readily apparent in view of FIG. 4.

FIG. 4 is a plan view of the front side 308 of the IC 302 in the device package 300 in FIG. 3 and is provided to illustrate an area A318 of the inductor coil 318 (determined by length L318×width W318) that may be available for use in the semiconductor die 306 with the inductor coil 318 (see FIG. 3) located on the back side 316 (see FIG. 3). FIG. 4 shows that, based on the available area A318, the power amplifier circuit 304 may be reorganized to fit into a smaller area on the front side 308. This savings may be offset, in part, by the addition of the via pads 330 for coupling the power amplifier circuit 304 to the through-die vias 320 (see FIG. 3) but makes possible an overall reduction in area and cost of the IC 302.

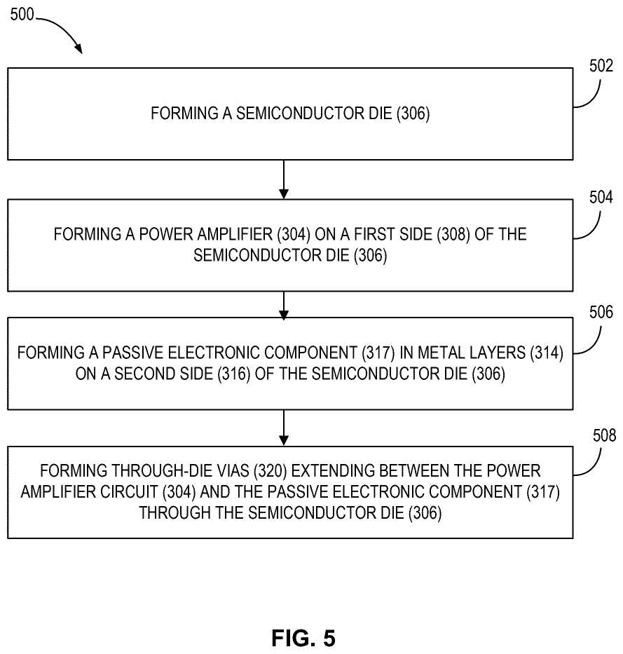

FIG. 5 a flowchart of a method 500 of making the IC 302 in FIGS. 3 and 4. The method includes forming a semiconductor die 306 (block 502) and forming a power amplifier circuit 304 on a first side 308 of the semiconductor die 306 (block 504). The method 500 further includes forming a passive electric component 317 in metal layers 314 on a second side 316 of the semiconductor die 306 (block 506) and forming through-die vias 320 extending between the power amplifier circuit 304 and the passive electric component 317 through the semiconductor die 306 (block 508).

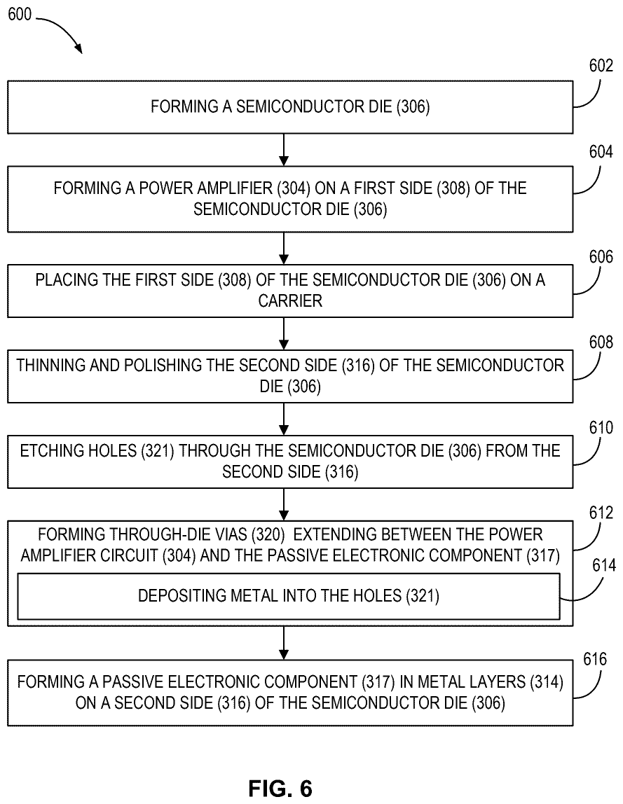

FIG. 6 is a flowchart of a more detailed method 600 of making the IC 302 in FIGS. 3 and 4. The method includes forming the semiconductor die 306 (block 602) and forming the power amplifier circuit 304 on the first side 308 of the semiconductor die 306 (block 604). The method 600 further includes placing the first side 308 of the semiconductor die 306 on a carrier (block 606) and thinning and polishing the second side 316 of the semiconductor die 306 (block 608). The method further includes etching holes 321 through the semiconductor die 306 from the second side 316 (block 610) and forming through-die vias 320 extending between the power amplifier circuit 304 and the passive electric component 317 (block 612), which further comprises depositing metal into the holes 321 (block 614). The method further includes forming the passive electric component 317 in metal layers 314 on the second side 316 of the semiconductor die 306 (block 616).

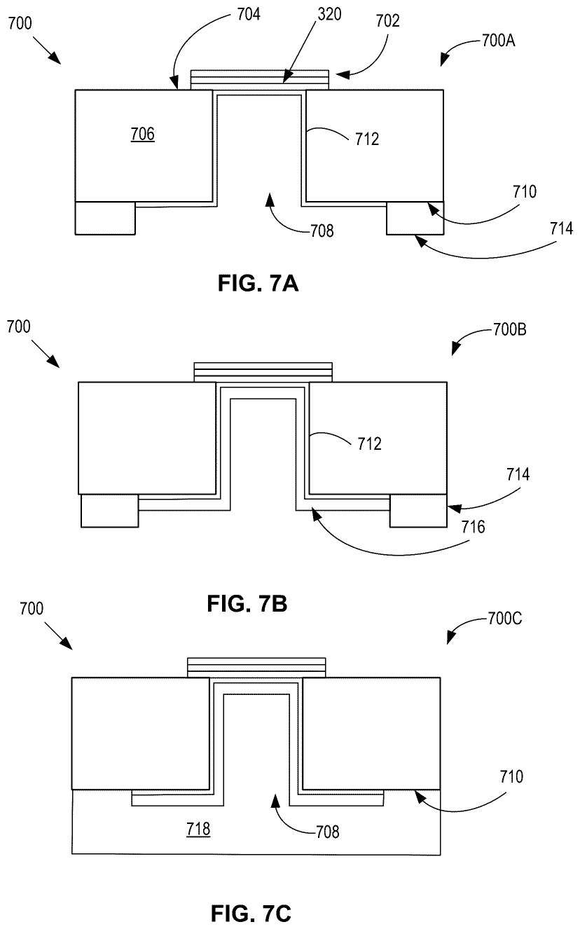

FIGS. 7A-7C are illustrations of a first example of a through-die via 700 in a semiconductor die at respective stages 700A-700C of manufacture, in one example. Manufacturing the through-die via 700 at stage 700A in FIG. 7A includes forming metal layers 702 on a front side 704 of a semiconductor die 706 to form the via pads 330 discussed above, etching a hole 708 through the semiconductor die 706 from a back side 710 to the front side 704, and depositing a seed metal layer 712 in the hole 708 and around the hole 708 on the back side 710 according to a photoresist pattern 714. Progressing to stage 700B in FIG. 7B includes depositing metal plating 716 over the seed metal layer 712 in the hole 708 and removing the photoresist pattern 714. Stage 700C in FIG. 7C shows a polymer 718 applied (e.g., by spin coating) to the back side 710 to fill the hole 708.

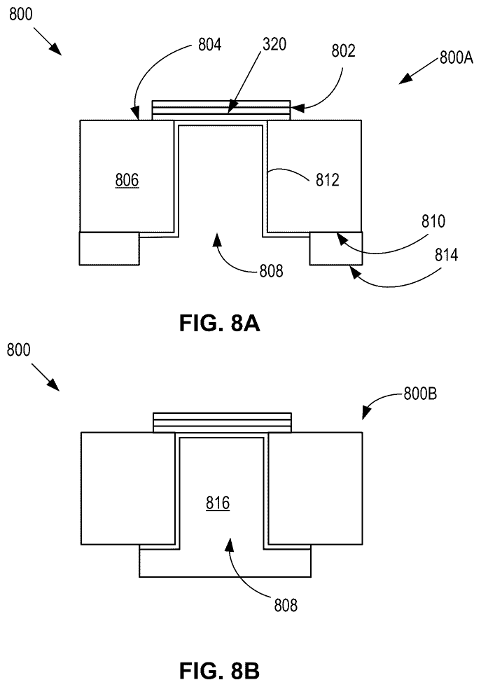

FIGS. 8A and 8B are illustrations of a second example of a through-die via 800 at stages 800A and 800B. The stage 800A in FIG. 8A in this example may be achieved in a same manner as the stage 700A in FIG. 7A, which includes forming metal layers 802 on a front side 804 of a semiconductor die 806 to form the via pads 330 discussed above, etching a hole 808 through the semiconductor die 806 from a back side 810, and depositing a seed metal layer 812 in the hole 808 and around the hole 808 on the front side 804 according to a photoresist pattern 814. In stage 800B in FIG. 8B the hole 808 is filled, not just plated, with metal 816 to form the through-die via 800.

Examples of such processor-based devices, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

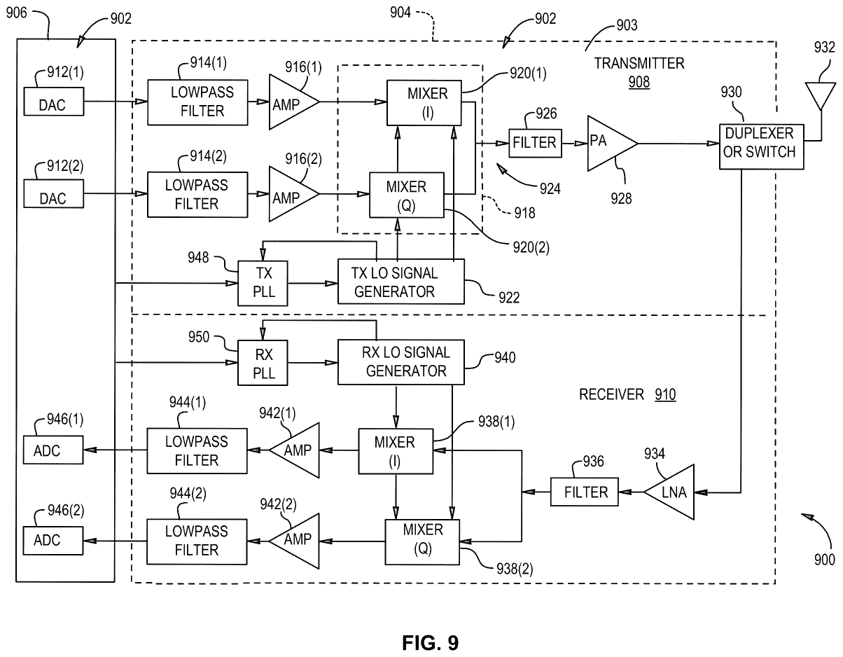

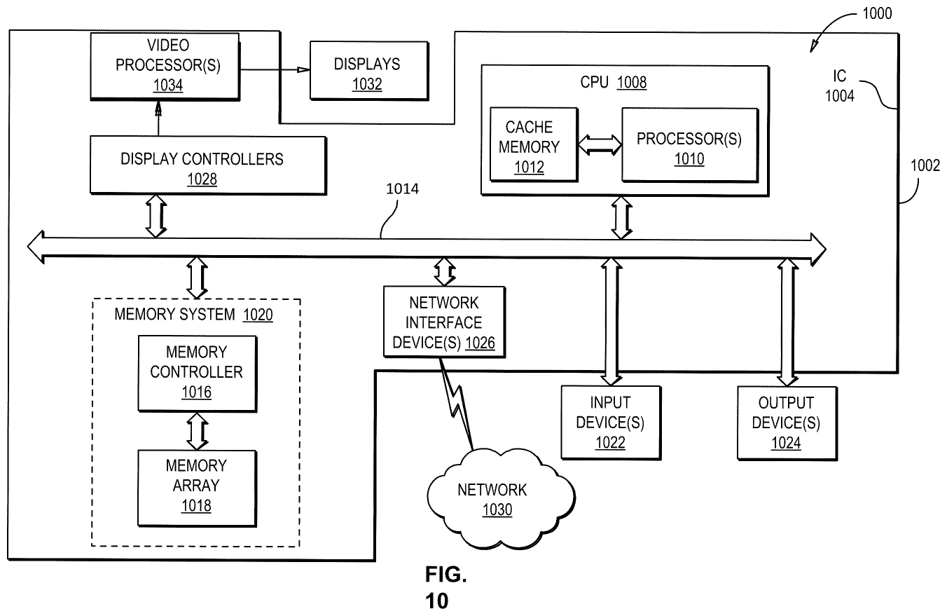

FIG. 9 illustrates an exemplary wireless communications device 900 that includes radio-frequency (RF) components formed from one or more ICs 902, wherein any of the ICs 902 may include clusters of logic circuits, such as processor cores, that include exemplary power management circuits to monitor circuit states and generate control signals with low latency to adjust circuit activity and maintain a higher level of performance, as shown in FIGS. 1-4. The wireless communications device 900 may include or be provided in any of the above-referenced devices, as examples. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage and then from IF to baseband in another stage for the receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals (e.g., I and Q output currents) for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals through mixers 920(1), 920(2) from a TX LO signal generator 922 to provide an upconverted signal 924. A filter 926 filters the upconverted signal 924 to remove undesired signals caused by the frequency up-conversion as well as noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Down-conversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency up-conversion, while the RX LO signal generator 940 generates the I and Q RX LO signals used for frequency down-conversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

In this regard, FIG. 10 illustrates an example of a processor-based system 1000 that can include clusters of logic circuits, such as processor cores, that include exemplary power management circuits to monitor circuit states and generate control signals with low latency to adjust circuit activity and maintain a higher level of performance, as shown in FIGS. 1-4. The processor-based system 1000 includes a central processing unit (CPU) 1008 that includes one or more processors 1010, which may also be referred to as CPU cores or processor cores. The CPU 1008 may have cache memory 1012 coupled to the CPU 1008 for rapid access to temporarily stored data. The CPU 1008 is coupled to a system bus 1014 and can intercouple master and slave devices included in the processor-based system 1000. As is well known, the CPU 1008 communicates with these other devices by exchanging address, control, and data information over the system bus 1014. For example, the CPU 1008 can communicate bus transaction requests to a memory controller 1016, as an example of a slave device. Although not illustrated in FIG. 10, multiple system buses 1014 could be provided, wherein each system bus 1014 constitutes a different fabric.

Other master and slave devices can be connected to the system bus 1014. As illustrated in FIG. 10, these devices can include a memory system 1020 that includes the memory controller 1016 and a memory array(s) 1018, one or more input devices 1022, one or more output devices 1024, one or more network interface devices 1026, and one or more display controllers 1028, as examples. The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow an exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1026 can be configured to support any type of communications protocol desired.

The CPU 1008 may also be configured to access the display controller(s) 1028 over the system bus 1014 to control information sent to one or more displays 1032. The display controller(s) 1028 sends information to the display(s) 1032 to be displayed via one or more video processor(s) 1034, which processes the information to be displayed into a format suitable for the display(s) 1032. The display(s) 1032 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:

1. An integrated circuit (IC) comprising:
a semiconductor die;
a power amplifier circuit on a first side of the semiconductor die;
a passive electric component in at least one metal layer on a second side of the semiconductor die; and
through-die vias extending between the power amplifier circuit and the passive electric component through the semiconductor die.
   2. The IC of clause 1, wherein the passive electric component comprises an inductor coil.
   3. The IC of clause 1 or clause 2, wherein the at least one metal layer on the second side of the semiconductor die comprises multiple metal layers forming a multi-layer inductor coil.
   4. The IC of any of clause 1 to clause 3, further comprising contact pads for conductive pillars on the first side of the semiconductor die and configured to couple the power amplifier circuit to a package substrate.
   5. The IC of clause 4, wherein the contact pads are further configured to provide power from the power amplifier circuit to a second circuit through the package substrate.
   6. The IC of any of clause 1 to clause 5, further comprising via pads on the first side of the semiconductor die to couple the through-die vias to the power amplifier circuit.
   7. The IC of any of clause 1 to clause 6, wherein the semiconductor die comprises one of a gallium arsenide (GaAs) substrate, silicon carbide (SiC), gallium nitride (GaN), silicon (Si), and sapphire.
   8. The IC of any of clause 1 to clause 7, wherein the semiconductor die has a thickness in a range of fifty microns (50 μm) to two hundred microns (200 μm) between the first side and the second side in a direction orthogonal to the second side of the semiconductor die.
   9. The IC of any of clause 1 to clause 8, wherein the through-die vias comprise metal vias having a diameter in a range of twenty microns (20 μm) to two hundred microns (200 μm).
   10. The IC of any of clause 1 to clause 9 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer;
a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
   11. A method of making an integrated circuit (IC), the method comprising:
forming a semiconductor die;
forming a power amplifier circuit on a first side of the semiconductor die;
forming a passive electric component in at least one metal layer on a second side of the semiconductor die; and
forming through-die vias extending between the power amplifier circuit and the passive electric component through the semiconductor die.
   12. The method of clause 11, further comprising:
placing the first side of the semiconductor die on a carrier;
polishing the second side of the semiconductor die;
etching holes through the semiconductor die from the second side;
depositing metal in the holes to form the through-die vias; and
forming the passive electric component in the at least one metal layer on the second side of the semiconductor die.
   13. A device package comprising:
a laminated substrate comprising a plurality of circuits;
an integrated circuit (IC) comprising:
   a semiconductor die;
   a power amplifier circuit on a first side of the semiconductor die;
   at least one metal layer configured to form a passive electric component on a second side of the semiconductor die; and
   through-die vias extending from the power amplifier circuit through the semiconductor die to the passive electric component; and
conductive pillars extending between the laminated substrate and the first side of the semiconductor die to couple the plurality of circuits to the power amplifier circuit.
   14. The device package of clause 13, wherein the passive electric component comprises an inductor.
   15. The device package of clause 13 or clause 14, wherein the at least one metal layer on the second side of the semiconductor die comprises a multi-layer inductor coil.
   16. The device package of any of clause 13 to clause 15, further comprising contact pads for the conductive pillars on the first side of the semiconductor die and configured to couple the power amplifier circuit to a package substrate.
   17. The device package of clause 16, wherein the contact pads are further configured to provide power from the power amplifier circuit to the plurality of circuits on the package substrate.
   18. The device package of any of clause 13 to clause 17, further comprising via pads on the first side of the semiconductor die to couple the through-die vias to the power amplifier circuit.
   19. The device package of any of clause 13 to clause 18, wherein the semiconductor die comprises one of a gallium arsenide (GaAs) substrate, silicon carbide (SiC), gallium nitride (GaN), silicon (Si), and sapphire.
   20. The device package of any of clause 13 to clause 19, wherein the semiconductor die has a thickness in a range of one hundred and forty microns (140 μm) to one hundred and sixty microns (160 μm) between the power amplifier circuit and the passive electric component in a direction orthogonal to the second side of the semiconductor die.

What is claimed is:

1. An integrated circuit (IC) comprising:
a semiconductor die;
a power amplifier circuit on a first side of the semiconductor die;
a passive electric component in at least one metal layer on a second side of the semiconductor die; and
through-die vias extending between the power amplifier circuit and the passive electric component through the semiconductor die.

2. The IC of claim 1, wherein the passive electric component comprises an inductor coil.

3. The IC of claim 1, wherein the at least one metal layer on the second side of the semiconductor die comprises multiple metal layers forming a multi-layer inductor coil.

4. The IC of claim 1, further comprising contact pads for conductive pillars on the first side of the semiconductor die and configured to couple the power amplifier circuit to a package substrate.

5. The IC of claim 4, wherein the contact pads are further configured to provide power from the power amplifier circuit to a second circuit through the package substrate.

6. The IC of claim 1, further comprising via pads on the first side of the semiconductor die to couple the through-die vias to the power amplifier circuit.

7. The IC of claim 1, wherein the semiconductor die comprises one of a gallium arsenide (GaAs) substrate, silicon carbide (SiC), gallium nitride (GaN), silicon (Si), and sapphire.

8. The IC of claim 1, wherein the semiconductor die has a thickness in a range of fifty microns (50 μm) to two hundred microns (200 μm) between the first side and the second side in a direction orthogonal to the second side of the semiconductor die.

9. The IC of claim 1, wherein the through-die vias comprise metal vias having a diameter in a range of twenty microns (20 μm) to two hundred microns (200 μm).

10. The IC of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

11. A method of making an integrated circuit (IC), the method comprising:
forming a semiconductor die;
forming a power amplifier circuit on a first side of the semiconductor die;
forming a passive electric component in at least one metal layer on a second side of the semiconductor die; and
forming through-die vias extending between the power amplifier circuit and the passive electric component through the semiconductor die.

12. The method of claim 11, further comprising:
placing the first side of the semiconductor die on a carrier;
polishing the second side of the semiconductor die;
etching holes through the semiconductor die from the second side;
depositing metal in the holes to form the through-die vias; and
forming the passive electric component in the at least one metal layer on the second side of the semiconductor die.

13. A device package comprising:
a laminated substrate comprising a plurality of circuits;
an integrated circuit (IC) comprising:
a semiconductor die;
a power amplifier circuit on a first side of the semiconductor die;
at least one metal layer configured to form a passive electric component on a second side of the semiconductor die; and
through-die vias extending from the power amplifier circuit through the semiconductor die to the passive electric component; and
conductive pillars extending between the laminated substrate and the first side of the semiconductor die to couple the plurality of circuits to the power amplifier circuit.

14. The device package of claim 13, wherein the passive electric component comprises an inductor.

15. The device package of claim 13, wherein the at least one metal layer on the second side of the semiconductor die comprises a multi-layer inductor coil.

16. The device package of claim 13, further comprising contact pads for the conductive pillars on the first side of the semiconductor die and configured to couple the power amplifier circuit to a package substrate.

17. The device package of claim 16, wherein the contact pads are further configured to provide power from the power amplifier circuit to the plurality of circuits on the package substrate.

18. The device package of claim 13, further comprising via pads on the first side of the semiconductor die to couple the through-die vias to the power amplifier circuit.

19. The device package of claim 13, wherein the semiconductor die comprises one of a gallium arsenide (GaAs) substrate, silicon carbide (SiC), gallium nitride (GaN), silicon (Si), and sapphire.

20. The device package of claim 19, wherein the semiconductor die has a thickness in a range of one hundred and forty microns (140 μm) to one hundred and sixty microns (160 μm) between the power amplifier circuit and the passive electric component in a direction orthogonal to the second side of the semiconductor die.
